(19) United States
(12) Patent Application Publication
(10) Pub. No.: US 2022/0029599 A1
(43) Pub. Date: Jan. 27, 2022

(54) ACOUSTIC WAVE DEVICE AND MULTIPLEXER

(71) Applicant: Murata Manufacturing Co., Ltd., Nagaokakyo-shi (JP)

(72) Inventors: Hideki IWAMOTO, Nagaokakyo-shi (JP); Akira MICHIGAMI, Nagaokakyo-shi (JP); Tsutomu TAKAI, Nagaokakyo-shi (JP); Takeshi NAKAO, Nagaokakyo-shi (JP)

(21) Appl. No.: 17/492,750

(22) Filed: Oct. 4, 2021

Related U.S. Application Data
(63) Continuation of application No. PCT/JP2020/015283, filed on Apr. 3, 2020.

(30) Foreign Application Priority Data
Apr. 8, 2019 (JP) 2019-073692

(51) Int. Cl. H03H 9/02; H03H 9/145; H03H 9/25; H03H 9/72

(52) U.S. Cl. CPC H03H 9/02574; H03H 9/02559; H03H 9/02637; H03H 9/72; H03H 9/145; H03H 9/25; H03H 9/02866

(57) ABSTRACT

An acoustic wave device includes a support substrate including silicon, a piezoelectric layer in which a rotated Y-cut X-propagation lithium tantalate is included, and an IDT electrode. A film thickness of the piezoelectric layer is less than or equal to about 1λ. When α₁₁₁ is an angle between a directional vector k₁₁₁, and a direction of silicon and n is an arbitrary integer, the angle α₁₁₁ is in a range of about 0°+120°×n≤α₁₁₁≤45°+120°×n or in a range of about 75°+120°×n≤α₁₁₁≤120°+120°×n when the IDT electrode is on a positive surface of the piezoelectric layer and the angle α₁₁₁ is in a range of about 15°+120°×n≤α₁₁₁≤105°+120°×n when the IDT electrode is on the negative surface of the piezoelectric layer.

### CROSS REFERENCE TO RELATED APPLICATIONS

This application claims the benefit of priority to Japanese Patent Application No. 2019-073692 filed on Apr. 8, 2019 and is a Continuation Application of PCT Application No. PCT/JP2020/015283 filed on Apr. 3, 2020. The entire contents of each application are hereby incorporated herein by reference.

### BACKGROUND OF THE INVENTION

### 1. Field of the Invention

The present invention relates to an acoustic wave device and a multiplexer.

### 2. Description of the Related Art

Heretofore, acoustic wave devices have been widely used in filters of mobile phone devices and so forth. International Publication No. 2017/209131 discloses an example of an acoustic wave device. The acoustic wave device includes a composite substrate including a piezoelectric single crystal substrate composed of lithium tantalate or the like and a silicon single crystal substrate bonded together. As the silicon single crystal substrate, an example is disclosed in which the plane orientation is Si(111) and Ψ in the Euler angles (φ, θ, Ψ) is 60°±15°. In addition, as the silicon single crystal substrate, an example is disclosed in which the plane orientation is Si(110) and Ψ is 0°±15°.

However, higher-order modes may be generated and the characteristics of the acoustic wave device may be degraded depending on the conditions under which the composite substrate is used in the acoustic wave device.

### SUMMARY OF THE INVENTION

Preferred embodiments of the present invention provide acoustic wave devices and multiplexers that are each able to effectively reduce or prevent higher-order modes.

An acoustic wave device according to a preferred embodiment of the present invention includes a support substrate including silicon and having a plane orientation of (111), a piezoelectric layer directly or indirectly provided on the support substrate and in which rotated Y-cut X-propagation lithium tantalate is included, and an IDT electrode including a plurality of electrode fingers and directly or indirectly provided on the piezoelectric layer. A film thickness of the piezoelectric layer is less than or equal to about 1λ, where λ is a wavelength defined by an electrode finger pitch of the IDT electrode. The piezoelectric layer includes a positive surface and a negative surface defined by a polarization direction. When (X_{LT}, Y_{LT}, Z_{LT}) are crystal axes of the lithium tantalate of the piezoelectric layer, k₁₁₁ is a directional vector obtained by projecting the Z_{LT} axis onto the (111) plane of the support substrate, α₁₁₁ is an angle between the directional vector k₁₁₁ and an [11-2] direction of the silicon of the support substrate, and n is an arbitrary integer (0, ±1, ±2, . . . ), the angle α₁₁₁ is in a range of about 0°+120°×n≤α₁₁₁≤45°+120°×n or is in a range of about 75°+120°×n≤α₁₁₁≤120°+120°×n when the IDT electrode is provided on the positive surface of the piezoelectric layer, and the angle α₁₁₁ is in a range of about 15°+120°×n≤α₁₁₁≤105°+120°×n when the IDT electrode is provided on the negative surface of the piezoelectric layer.

An acoustic wave device according to a preferred embodiment of the present invention includes a support substrate including silicon and having a plane orientation of (110), a piezoelectric layer directly or indirectly provided on the support substrate and in which rotated Y-cut X-propagation lithium tantalate is included, and an IDT electrode including a plurality of electrode fingers and provided on the piezoelectric layer. A film thickness of the piezoelectric layer is less than or equal to about 1λ, where λ is a wavelength defined by an electrode finger pitch of the IDT electrode. When (X_{LT}, Y_{LT}, Z_{LT}) are crystal axes of the lithium tantalate of the piezoelectric layer, k₁₁₀ is a directional vector obtained by projecting the Z_{LT} axis onto the (110) plane of the support substrate, α₁₁₀ is an angle between the directional vector k₁₁₀ and a [001] direction of the silicon of the support substrate, and n is an arbitrary integer (0, ±1, ±2, . . . ), the angle α₁₁₀ is in a range of about 0°+180°×n≤α₁₁₀≤40°+180°×n or is in a range of about 140°+180°×n≤α₁₁₀≤180°+180°×n.

An acoustic wave device according to a preferred embodiment of the present invention includes a support substrate including silicon and having a plane orientation of (100), a piezoelectric layer directly or indirectly provided on the support substrate and in which rotated Y-cut X-propagation lithium tantalate is included, and an IDT electrode including a plurality of electrode fingers and provided on the piezoelectric layer. A film thickness of the piezoelectric layer is less than or equal to about 1λ, where λ is a wavelength defined by an electrode finger pitch of the IDT electrode. When (X_{LT}, Y_{LT}, Z_{LT}) are crystal axes of the lithium tantalate of the piezoelectric layer, k₁₀₀ is a directional vector obtained by projecting the Z_{LT} axis onto the (100) plane of the support substrate, α₁₀₀ is an angle between the directional vector k₁₀₀ and a [001] direction of the silicon of the support substrate, and n is an arbitrary integer (0, ±1, ±2, . . . ), the angle α₁₀₀ is in a range of about 20°+90°×n≤α₁₀₀≤70°+90°×n.

A multiplexer according to a preferred embodiment of the present invention includes a signal terminal, and a plurality of filter devices commonly connected to the signal terminal and each including an acoustic wave device according to a preferred embodiment of the present invention and having different pass bands from each other. A cut angle of the piezoelectric layer of the acoustic wave device of one filter device among the plurality of filter devices and a cut angle of the piezoelectric layer of the acoustic wave device of at least one other filter device among the plurality of filter devices are different from each other.

With acoustic wave devices and multiplexers according to preferred embodiments of the present invention, higher-order modes are able to be effectively reduced or prevented.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a plan view of an acoustic wave device according to a First Preferred Embodiment of the present invention.

FIG. 2 is a front sectional view of the acoustic wave device according to the First Preferred Embodiment of the present invention.

FIG. 3 is a schematic diagram illustrating definitions of an X_{LT} axis, a Y_{LT} axis, and a Z_{LT} axis, and a polarization direction of the crystal structure of LiTaO₃.

FIGS. 4A to 4E are diagrams illustrating the crystal orientation of 55° Y-cut X-propagation LiTaO₃ according to the definitions illustrated in FIG. 3.

FIG. 5 is a schematic diagram illustrating definitions of the crystal axes of silicon.

FIG. 6 is a schematic diagram illustrating the (111) plane of silicon.

FIG. 7 is a diagram in which the crystal axes of the (111) plane of silicon are seen from the XY plane.

FIG. 8 is a schematic sectional view for describing a directional vector k₁₁₁.

FIG. 9 is a schematic sectional view for describing a directional vector k₁₁₁.

FIG. 10 is a schematic diagram illustrating the [11-2] direction of silicon.

FIG. 11 is a schematic diagram for describing an angle α₁₁₁.

FIG. 12 is a diagram illustrating the relationship between the angle α₁₁₁ and the phase of a higher-order mode in a case where an IDT electrode is provided on a positive surface of a piezoelectric layer and the crystal orientation of the piezoelectric layer is (0°, −35°, 0°).

FIG. 13 is a diagram illustrating the relationship between the angle α₁₁₁ and the phase of a higher-order mode in a case where an IDT electrode is provided on a positive surface of a piezoelectric layer and the crystal orientation of the piezoelectric layer is (0°, −35°, 180°).

FIG. 14 is a diagram illustrating the relationship between the angle α₁₁₁ and the phase of a higher-order mode in a case where an IDT electrode is provided on a negative surface of a piezoelectric layer and the crystal orientation of the piezoelectric layer is (0°, 145°, 0°).

FIG. 15 is a diagram illustrating the relationship between the angle α₁₁₁ and the phase of a higher-order mode in a case where an IDT electrode is provided on a negative surface of a piezoelectric layer and the crystal orientation of the piezoelectric layer is (0°, 145°, 180°).

FIG. 16 is a front sectional view of an acoustic wave device according to a Second Preferred Embodiment of the present invention.

FIG. 17 is a diagram illustrating the relationship between the angle α₁₁₁ and the phase of a higher-order mode in a case where an IDT electrode is provided on a positive surface of a piezoelectric layer and the crystal orientation of the piezoelectric layer is (0°, −35°, 0°).

FIG. 18 is a diagram illustrating the relationship between the angle α₁₁₁ and the phase of a higher-order mode in a case where an IDT electrode is provided on a positive surface of a piezoelectric layer and the crystal orientation of the piezoelectric layer is (0°, −35°, 180°).

FIG. 19 is a diagram illustrating the relationship between the angle α₁₁₁ and the phase of a higher-order mode in a case where an IDT electrode is provided on a negative surface of a piezoelectric layer and the crystal orientation of the piezoelectric layer is (0°, 145°, 0°).

FIG. 20 is a diagram illustrating the relationship between the angle α₁₁₁ and the phase of a higher-order mode in a case where an IDT electrode is provided on a negative surface of a piezoelectric layer and the crystal orientation of the piezoelectric layer is (0°, 145°, 180°).

FIG. 21 is a front sectional view of an acoustic wave device according to a Third Preferred Embodiment of the present invention.

FIG. 22 is a diagram illustrating the relationship between the angle α₁₁₁ and the phase of a higher-order mode in a case where an IDT electrode is provided on a positive surface of a piezoelectric layer and the crystal orientation of the piezoelectric layer is (0°, −35°, 0°).

FIG. 23 is a diagram illustrating the relationship between the angle α₁₁₁ and the phase of a higher-order mode in a case where an IDT electrode is provided on a positive surface of a piezoelectric layer and the crystal orientation of the piezoelectric layer is (0°, −35°, 180°).

FIG. 24 is a diagram illustrating the relationship between the angle α₁₁₁ and the phase of a higher-order mode in a case where an IDT electrode is provided on a negative surface of a piezoelectric layer and the crystal orientation of the piezoelectric layer is (0°, 145°, 0°).

FIG. 25 is a diagram illustrating the relationship between the angle α₁₁₁ and the phase of a higher-order mode in a case where an IDT electrode is provided on a negative surface of a piezoelectric layer and the crystal orientation of the piezoelectric layer is (0°, 145°, 180°).

FIG. 26 is a schematic diagram illustrating the (110) plane of silicon.

FIG. 27 is a diagram illustrating the relationship between an angle α₁₁₁ and the phase of a higher-order mode in a case where the crystal orientation of the piezoelectric layer is (0°, 145°, 0°).

FIG. 28 is a schematic diagram illustrating the (100) plane of silicon.

FIG. 29 is a diagram illustrating the relationship between an angle α₁₀₀ and the phase of a higher-order mode in a case where the crystal orientation of the piezoelectric layer is (0°, 145°, 0°).

FIG. 30 is a schematic diagram of a multiplexer according to a Sixth Preferred Embodiment of the present invention.

FIG. 31 is a diagram illustrating the relationship between the cut angle of LiTaO₃ of the piezoelectric layer and the relative bandwidth of a Rayleigh wave.

### DETAILED DESCRIPTION OF THE PREFERRED EMBODIMENTS

Hereafter, the present invention will be made clearer by describing preferred embodiments of the present invention while referring to the drawings.

The preferred embodiments described in the present specification are illustrative examples and portions of the configurations illustrated in different preferred embodiments can be substituted for one another or combined with one another.

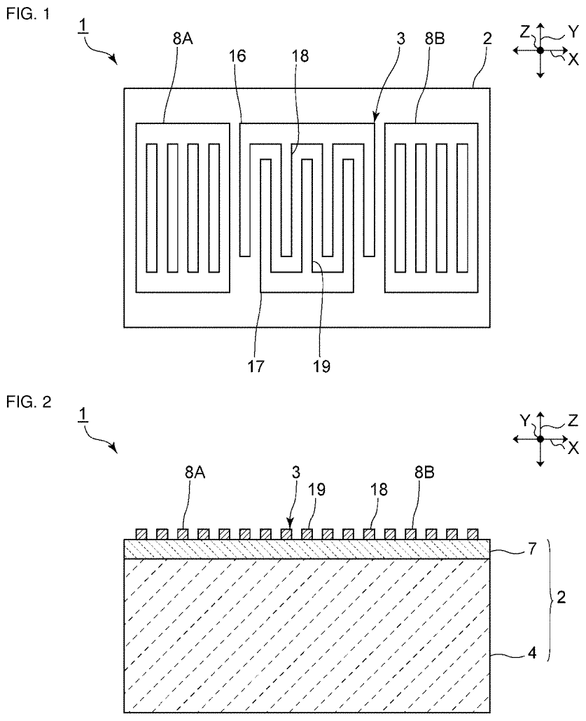

FIG. 1 is a plan view of an acoustic wave device according to a First Preferred Embodiment of the present invention.

An acoustic wave device 1 includes a piezoelectric substrate 2. An IDT electrode 3 is provided on the piezoelectric substrate 2. Acoustic waves are excited by applying an alternating-current voltage to the IDT electrode 3. In the present specification, the propagation direction of surface acoustic waves (SAWs) is an X direction, a direction perpendicular or substantially perpendicular to the X direction is a Y direction, and a direction perpendicular or substantially perpendicular to the X direction and the Y direction is a Z direction. The Z direction is the thickness direction of the piezoelectric substrate 2. A pair of reflectors, particularly, a reflector 8A and a reflector 8B are provided on the piezoelectric substrate 2 on both sides of the IDT electrode 3 in the X direction. The acoustic wave device 1 of the present preferred embodiment is an acoustic wave resonator, for example. However, the acoustic wave device 1 according to the present preferred embodiment is not limited to being an acoustic wave resonator, and may be a filter device including a plurality of acoustic wave resonators, for example.

The IDT electrode 3 includes a first busbar 16 and a second busbar 17 facing each other. The IDT electrode 3 includes a plurality of first electrode fingers 18 including first ends connected to the first busbar 16. In addition, the IDT electrode 3 includes a plurality of second electrode fingers 19 including first ends connected to the second busbar 17. The plurality of first electrode fingers 18 and the plurality of second electrode fingers 19 are interdigitated with each other. The first electrode fingers 18 and the second electrode fingers 19 extend in the Y direction.

The IDT electrode 3 includes a single-layer Al film, for example. The material of the reflector 8A and the reflector 8B is the same as the material of the IDT electrode 3. The materials of the IDT electrode 3, the reflector 8A, and the reflector 8B are not limited to the above-described material. Alternatively, the IDT electrode 3, the reflector 8A, and the reflector 8B may include, for example, multilayer metal films in which a plurality of metal layers are stacked.

FIG. 2 is a front sectional view of the acoustic wave device according to the First Preferred Embodiment.

The piezoelectric substrate 2 of the acoustic wave device 1 includes a support substrate 4 and a piezoelectric layer 7 provided directly on the support substrate 4. The IDT electrode 3 and the reflector 8A and the reflector 8B are provided on the piezoelectric layer 7. In the present preferred embodiment, the IDT electrode 3 is directly provided on the piezoelectric layer 7. However, the IDT electrode 3 may instead be indirectly provided on the piezoelectric layer 7 with a dielectric film interposed therebetween.

The piezoelectric layer 7 is, for example, a lithium tantalate layer. More specifically, 55° Y-cut X-propagation LiTaO₃ is preferably used for the piezoelectric layer 7. The cut angle of the piezoelectric layer 7 is not limited to the above-described cut angle. The film thickness of the piezoelectric layer 7 is, for example, less than or equal to about 1λ , where λ is a wavelength defined by the electrode finger pitch of the IDT electrode 3.

The piezoelectric layer 7 includes a negative surface and a positive surface in the polarization direction. In this specification, a direction from “−” to “+” in a polarized state is defined as a +Z_{LT} direction. The +Z_{LT} direction is a polarization direction of the LiTaO₃ of the piezoelectric layer 7.

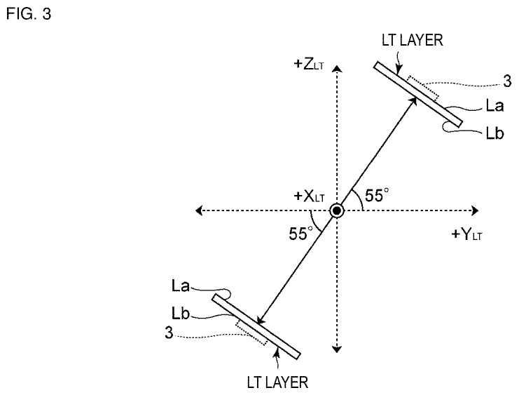

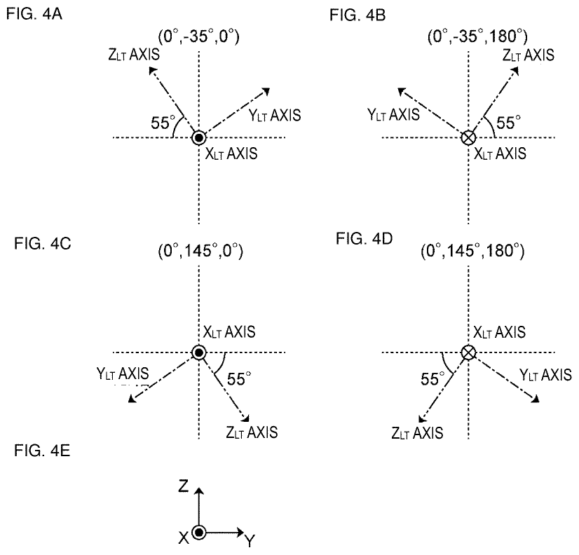

FIG. 3 is a schematic diagram illustrating definitions of an X_{LT} axis, a Y_{LT} axis, and a Z_{LT} axis, and a polarization direction of the crystal structure of LiTaO₃. Here, a +X_{LT} direction is a direction perpendicular or substantially perpendicular to the +Z_{LT} direction and is parallel or substantially parallel to the propagation direction (X direction) of SAWs. A +Y_{LT} direction is a direction perpendicular or substantially perpendicular to both an X_{LT} direction and a Z_{LT} direction. The crystal axes of LiTaO₃ of the piezoelectric layer in this specification are (X_{LT}, Y_{LT}, Z_{LT}). FIG. 3 illustrates an example of a case in which the cut angle is about 55° Y. FIGS. 4A to 4D are diagrams illustrating the crystal orientation of 55° Y-cut X-propagation LiTaO₃ according to the definitions illustrated in FIG. 3.

The LiTaO₃ layer (LT layer) illustrated in FIG. 3 includes a positive surface La on the positive side in the polarization direction and a negative surface Lb on the negative side in the polarization direction. In the upper right region of FIG. 3, a case is illustrated in which the IDT electrode 3 is provided on the positive surface La side. At this time, the negative surface Lb is the surface on the side adjacent to the support substrate 4. On the other hand, in the lower left region of FIG. 3, a case is illustrated in which the IDT electrode 3 is provided on the negative surface side. At this time, the positive surface La is the surface on the side adjacent the support substrate 4. The term “positive surface” in this specification refers to a main surface where about 95% or more of the surface defines a positively polarized surface in the polarization direction. In addition, the term “negative surface” in this specification refers to a main surface where about 95% or more of the surface defines a negatively polarized surface in the polarization direction.

According to the definitions illustrated in FIG. 3, 55° Y-cut X-propagation LiTaO₃ can exist in the four crystal orientations illustrated in FIGS. 4A to 4D, depending on the combination of the polarization direction and the Z_{LT} axis direction of LiTaO₃. Here, FIGS. 4A to 4D illustrate the X_{LT}, Y_{LT}, and Z_{LT} directions when looking from the X direction side illustrated in FIG. 4E. More specifically, FIGS. 4A and 4B illustrate a case in which the IDT electrode 3 is provided on the positive surface of the piezoelectric layer 7. FIG. 4A illustrates a case in which the Z_{LT} direction, which is the polarization direction, is inclined toward the −Y direction and FIG. 4B illustrates a case in which the Z_{LT} direction is inclined toward the +Y direction. In the case of the crystal orientation illustrated in FIG. 4A, for example, the Euler angles are (0°, −35°, 0°). In the case of the crystal orientation illustrated in FIG. 4B, for example, the Euler angles are (0°, −35°, 180°). On the other hand, FIGS. 4C and 4D illustrate a case in which the IDT electrode 3 is provided on the negative surface of the piezoelectric layer 7. FIG. 4C illustrates a case in which the Z_{LT} direction is inclined toward the +Y direction and FIG. 4D illustrates a case in which the Z_{LT} direction is inclined toward the −Y direction. In the case of the crystal orientation illustrated in FIG. 4C, for example, the Euler angles are (0°, 145°, 0°). In the case of the crystal orientation illustrated in FIG. 4D, for example, the Euler angles are (0°, 145°, 180°).

Next, the definitions of the Euler angles will be described. When the Euler angles are (φ, θ, Ψ), (1) (x, y, z) is rotated around the z axis by “φ” to give (x1, y1, z1). Next, (2) (x1, y1, z1) is rotated around the x1 axis by “θ” to give (x2, y2, z2). Next, (3) (x2, y2, z2) is rotated around the z2 axis by “Ψ” to give an orientation (x3, y3, z3). Here, a right-hand screw direction is a positive rotation direction. (x, y, z) becomes (x3, y3, z3) through the above-described rotational operations (1) to (3). The coordinate systems of (x, y, z) and (x3, y3, z3) have a common origin. Hereafter, a case where the Euler angles are (φ, θ, Ψ) may be written as a crystal orientation of (φ, θ, Ψ). The Euler angles and the coordinate transformation method are also described in “Danseihasoshigijutsu Handobukku, pg. 549”.

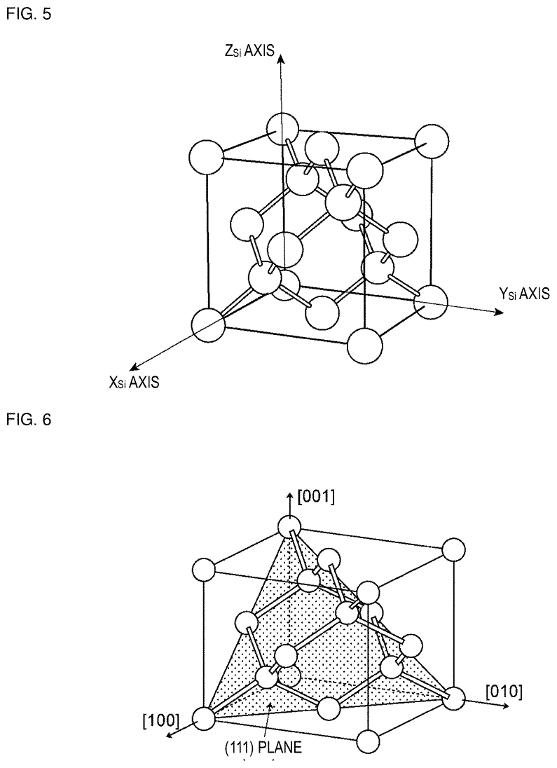

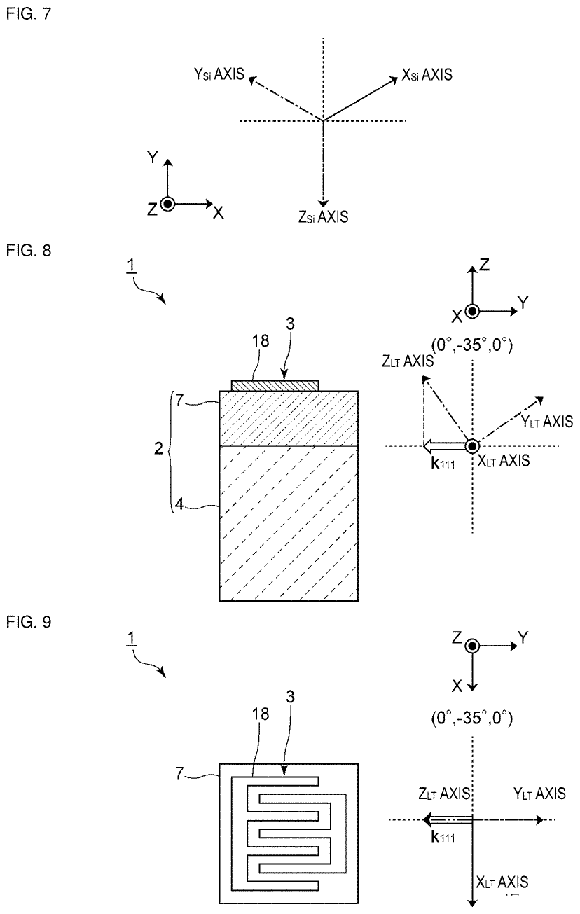

FIG. 5 is a schematic diagram illustrating definitions of the crystal axes of silicon. FIG. 6 is a schematic diagram illustrating the (111) plane of silicon. FIG. 7 is a diagram in which the crystal axes of the (111) plane of silicon are viewed from the XY plane.

The support substrate 4 is a silicon substrate. As illustrated in FIG. 5, silicon has a diamond structure. In this specification, the crystal axes of the silicon of the support substrate 4 are (X_{Si}, Y_{Si}, Z_{Si}). In silicon, the X_{Si} axis, the Y_{Si}, axis, and the Z_{Si} axis are equivalent to each other due to the symmetry of the crystal structure. As illustrated in FIG. 7, the crystal structure has three-fold symmetry in the (111) plane and becomes an equivalent crystal structure when rotated through 120°.

The plane orientation of the support substrate 4 in the present preferred embodiment is Si(111). “Si(111)” indicates that the substrate has been cut along the (111) plane perpendicular or substantially perpendicular to the crystal axis represented by the Miller index [111] in a silicon crystal structure having a diamond structure. The (111) plane is the plane illustrated in FIGS. 6 and 7. However, other crystallographically equivalent planes are also included.

Here, n is an arbitrary integer (0, ±1, ±2, . . . ). In the present preferred embodiment, when the IDT electrode 3 is provided on the positive surface of the piezoelectric layer 7, the angle α₁₁₁ defined from the relationship between the crystal axes of the piezoelectric layer 7 and the support substrate 4 is in the range of about 0°+120°×n≤α₁₁₁≤45°+120°×n or in the range of about 75°+120°×n≤α₁₁₁≤120°+120°×n. On the other hand, when the IDT electrode 3 is provided on the negative surface of the piezoelectric layer 7, the angle α₁₁₁ is in the range of about 15°+120°×n≤α₁₁₁≤105°+120°×n. Hereafter, the angle Um and a directional vector k₁₁₁, which will be described later, are described in detail.

FIG. 8 is a schematic sectional view for describing the directional vector k₁₁₁. FIG. 9 is a schematic sectional view for describing the directional vector k₁₁₁.

In FIGS. 8 and 9, an example is illustrated in which the IDT electrode 3 is provided on the positive surface of the piezoelectric layer 7. More specifically, a case is illustrated in which the Euler angles of the piezoelectric layer 7 are (0°, −35°, 0°). The (111) plane of the support substrate 4 contacts the piezoelectric layer 7.

Here, as illustrated in FIG. 8, km is a directional vector obtained when the Z_{LT} axis of LiTaO₃ of the piezoelectric layer 7 is projected onto the (111) plane of the support substrate 4. As illustrated in FIGS. 8 and 9, the directional vector k₁₁₁ is parallel or substantially parallel to the Y direction, which is the direction in which the electrode fingers of the IDT electrode 3 extend.

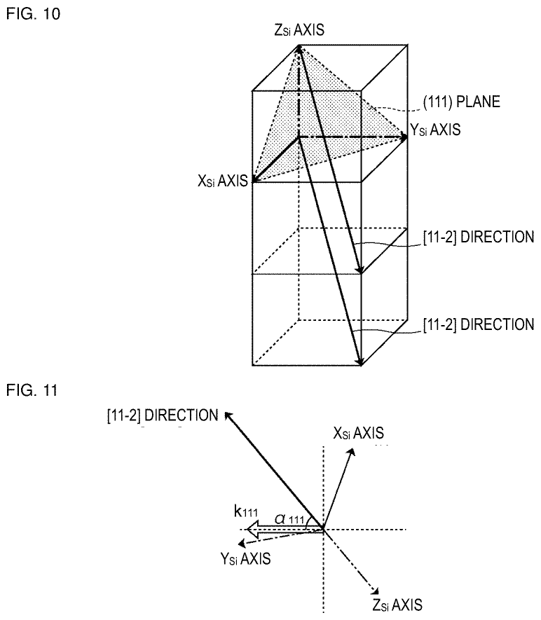

FIG. 10 is a schematic diagram illustrating the [11-2] direction of silicon. FIG. 11 is a schematic diagram for describing the angle α₁₁₁.

As illustrated in FIG. 10, the [11-2] direction of silicon is illustrated as a composite vector of a unit vector in the X_{Si} direction, a unit vector in the Y_{Si} direction, and a vector that is −2 times a unit vector in the Z_{Si} direction in the crystal structure of silicon. As illustrated in FIG. 11, the angle α₁₁₁ is the angle between the directional vector k₁₁₁ and the [11-2] direction of the silicon of the support substrate 4. As described above, [11-2], [1-21], and [−211] are equivalent to each other from the crystal symmetry of silicon.

The present preferred embodiment has the following features. 1) The present preferred embodiment includes the support substrate 4 having a plane orientation of Si(111) and the piezoelectric layer 7 in which rotated Y-cut X-propagation LiTaO₃ is used. 2a) When the IDT electrode 3 is provided on the positive surface of the piezoelectric layer 7, the angle α₁₁₁ is in the range of about 0°+120°×n≤α₁₁₁≤45°+120°×n or is in the range of about 75°+120°×n≤α₁₁₁≤120°+120°×n. 2) When the IDT electrode 3 is provided on the negative surface of the piezoelectric layer 7, the angle α₁₁₁ is in the range of about 15°+120°×n≤α₁₁₁≤105°+120°×n. As a result, a higher-order mode can be effectively reduced or prevented. This will be explained below.

The relationship between the angle α₁₁₁ and the phase of a higher-order mode was determined for the case where the IDT electrode is provided on the positive surface of the piezoelectric layer and the case where the IDT electrode is provided on the negative surface of the piezoelectric layer. The higher-order mode for which the relationship with the angle α₁₁₁ was obtained is a higher-order mode generated in the vicinity of about 2500 MHz to about 3000 MHz. The conditions of the acoustic wave device are listed below. Note that, for example, when the film thickness is about 1% λ, the film thickness is about 0.01λ.

Support substrate: Material . . . silicon (Si), Plane orientation . . . Si(111)

Piezoelectric layer: Material . . . rotated Y-cut X-propagation LiTaO₃, Film thickness . . . 0.2λ, Crystal orientation of LiTaO₃ of piezoelectric layer: (0°, −35°, 0°), (0°, −35°, 180°), (0°, 145°, 0), or (0, 145°, 180°)

IDT electrode: Material . . . Al, Film thickness . . . about 5% λ, Wavelength λ of IDT electrode: about 2 μm

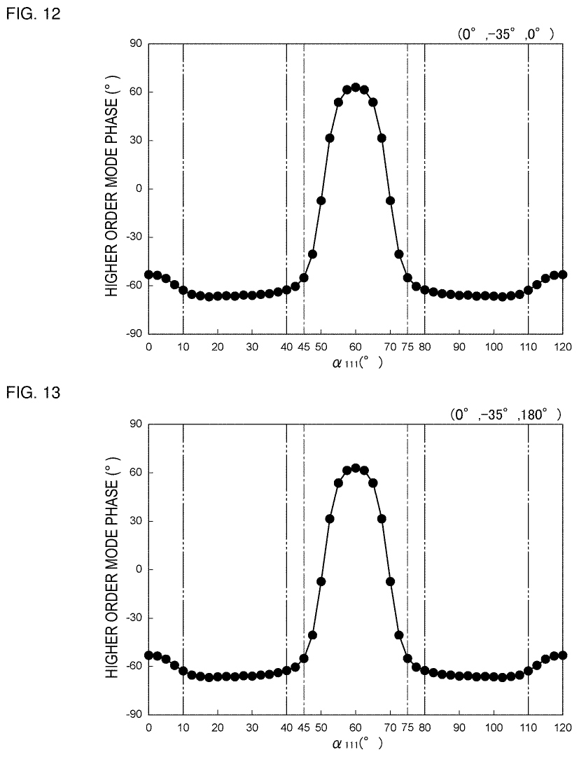

FIG. 12 is a diagram illustrating the relationship between the angle α₁₁ and the phase of the higher-order mode in a case where the IDT electrode is provided on the positive surface of the piezoelectric layer and the crystal orientation of the piezoelectric layer is (0°, −35°, 0°). FIG. 13 is a diagram illustrating the relationship between the angle α₁₁₁ and the phase of the higher-order mode in a case where the IDT electrode is provided on the positive surface of the piezoelectric layer and the crystal orientation of the piezoelectric layer is (0°, −35°, 180°).

As illustrated in FIGS. 12 and 13, in the case where the IDT electrode is provided on the positive surface of the piezoelectric layer, it is clear that the higher-order mode is effectively reduced or prevented when the angle α₁₁₁ is in a range from about 0° to about 45°, for example. Similarly, it is clear that the higher-order mode is effectively reduced or prevented when the angle α₁₁₁ is in a range from about 75° to about 120°, for example. Here, when the plane orientation of the support substrate is Si(111), α₁₁₁=α₁₁₁+120° due the symmetry of the crystal structure. Therefore, the higher-order mode can be effectively reduced or prevented when the IDT electrode is provided on the positive surface of the piezoelectric layer and α₁₁₁ is in the range of about 0°+120°×n≤α₁₁₁≤45°+120°×n or in the range of about 75°+120°×n≤α₁₁₁≤120°+120°×n.

Furthermore, it is clear that the higher-order mode can be more greatly reduced or prevented when the angle α₁₁₁ is in the range from about 10° to about 40° or in the range from about 80° to about 110°, for example. Thus, when the IDT electrode is provided on the positive surface of the piezoelectric layer, it is preferable that α₁₁₁ is in the range of about 10°+120°×n≤α₁₁₁≤40°+120°×n or in the range of about 80°+120°×n≤α₁₁₁≤110°+120°×n.

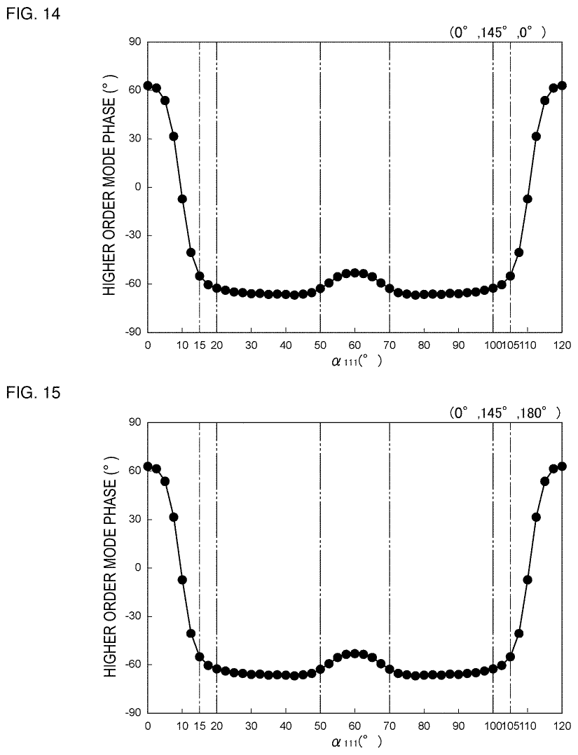

FIG. 14 is a diagram illustrating the relationship between the angle α₁₁₁ and the phase of the higher-order mode in a case where the IDT electrode is provided on the negative surface of the piezoelectric layer and the crystal orientation of the piezoelectric layer is (0°, 145°, 0°). FIG. 15 is a diagram illustrating the relationship between the angle α₁₁₁ and the phase of the higher-order mode in a case where the IDT electrode is provided on the negative surface of the piezoelectric layer and the crystal orientation of the piezoelectric layer is (0°, 145°, 180°).

It is clear that the relationships between the angle am and the phase of the higher-order mode are different in the case where the IDT electrode is provided on the negative surface of the piezoelectric layer as illustrated in FIGS. 14 and 15 and in the case where the IDT electrode is provided on the positive surface of the piezoelectric layer as illustrated in FIGS. 12 and 13. More specifically, it is clear that the higher-order mode is effectively reduced or prevented when the angle α₁₁₁ is in a range from about 15° to about 105°, for example. Therefore, the higher-order mode can be effectively reduced or prevented when the IDT electrode is provided on the negative surface of the piezoelectric layer and α₁₁₁ is in the range of about 15°+120°×n≤α₁₁₁≤105°+120°×n.

Furthermore, it is clear that the higher-order mode can be more greatly reduced or prevented when the angle α₁₁₁ is in the range from about 20° to about 50° or in the range from about 70° to about 100°, for example. Thus, when the IDT electrode is provided on the negative surface of the piezoelectric layer, it is preferable that α₁₁₁ is within the range of about 20°+120°×n≤α₁₁₁≤50°+120°×n or within the range of about 70°+120°×n≤α₁₁₁≤100°+120°×n.

An uneven structure may be provided on a surface of the support substrate 4 illustrated in FIG. 1 that is on the side near the piezoelectric layer 7. In this case, non-linear characteristics can be improved. The uneven structure may be formed by performing grinding or another method, or may be a random uneven structure.

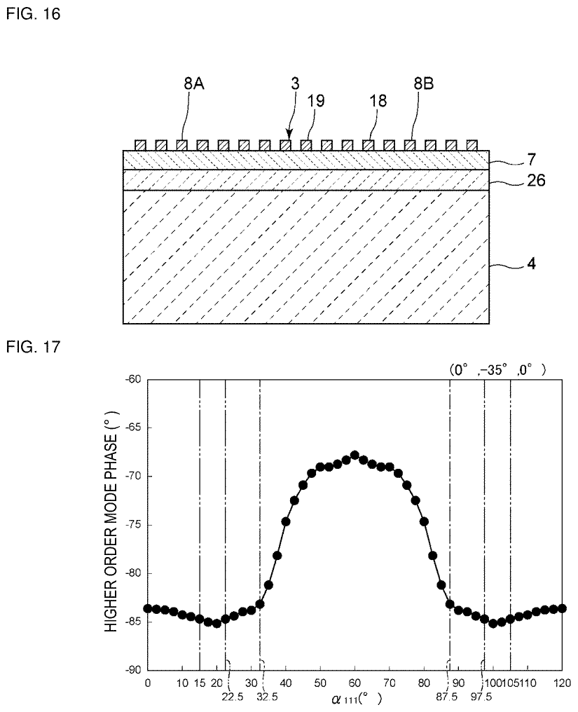

FIG. 16 is a front sectional view of an acoustic wave device according to a Second Preferred Embodiment of the present invention.

The present preferred embodiment differs from the First Preferred Embodiment in that a low-acoustic-velocity film 26 is provided between the support substrate 4 and the piezoelectric layer 7. Thus, the piezoelectric layer 7 may be indirectly provided on the support substrate 4 with the low-acoustic-velocity film 26 interposed therebetween. In other respects, the acoustic wave device of the present preferred embodiment has the same or substantially the same configuration as the acoustic wave device 1 of the First Preferred Embodiment.

The low-acoustic-velocity film 26 is a film having a relatively low acoustic velocity. More specifically, the acoustic velocity of bulk waves propagating through the low-acoustic-velocity film 26 is lower than the acoustic velocity of bulk waves propagating through the piezoelectric layer 7. The low-acoustic-velocity film 26 in the present preferred embodiment is a silicon oxide film, for example. The silicon oxide is expressed as SiOₓ. x is an arbitrary integer. The silicon oxide of the low-acoustic-velocity film 26 in the present preferred embodiment is SiO₂, for example. The material of the low-acoustic-velocity film 26 is not limited to the above material and, for example, a material having glass, silicon oxynitride, tantalum oxide, or a compound obtained by adding fluorine, carbon, or boron to silicon oxide as a main component can be used.

The relationship between the angle α₁₁₁ and the phase of the higher-order mode was obtained for a case in which the IDT electrode was provided on the positive surface of the piezoelectric layer and a case in which the IDT electrode was provided on the negative surface of the piezoelectric layer under conditions differing from the those under which the relationships in FIGS. 12 to 15 were obtained only in that the low-acoustic-velocity film was provided.

Low-acoustic-velocity film: Material . . . SiO₂, Film thickness . . . about 0.15λ

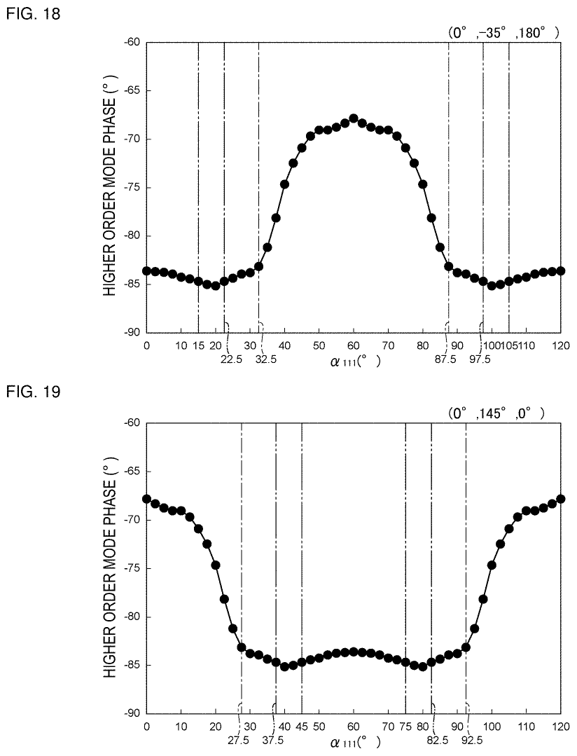

FIG. 17 is a diagram illustrating the relationship between the angle α₁₁₁ and the phase of the higher-order mode in a case where the IDT electrode is provided on the positive surface of the piezoelectric layer and the crystal orientation of the piezoelectric layer is (0°, −35°, 0°). FIG. 18 is a diagram illustrating the relationship between the angle α₁₁₁ and the phase of the higher-order mode in a case where the IDT electrode is provided on the positive surface of the piezoelectric layer and the crystal orientation of the piezoelectric layer is (0°, −35°, 180°).

As illustrated in FIGS. 17 and 18, it is clear that the higher-order mode can be more greatly reduced or prevented when the low-acoustic-velocity film is provided compared to the case illustrated in FIGS. 12 and 13. Furthermore, it is clear that the higher-order mode can be more effectively reduced or prevented when the angle α₁₁₁ is in the range from about 0° to about 32.5° or in the range from about 87.5° to about 120°. Note that α₁₁₁=87.5° is equivalent to α₁₁₁=−32.5° and α₁₁₁=120° is equivalent to α₁₁₁=0° due to the symmetry of the crystal structure. Furthermore, it is clear that the higher-order mode can be even more greatly reduced or prevented when the angle α₁₁₁ is in the range from 15° to 22.5° or in in the range from 97.5° to 105°, for example. Thus, it is preferable that α₁₁₁ is in the range of about 0°+120°×n≤α₁₁₁≤32.5°+120°×n or in the range of about 87.5°+120°×n≤α₁₁₁≤120°+120°×n. It is still more preferable that α₁₁₁ is in the range of about 15°+120°×n≤α₁₁₁≤22.5°+120°×n or in the range of about 97.5°+120°×n≤α₁₁₁≤105°+120°×n.

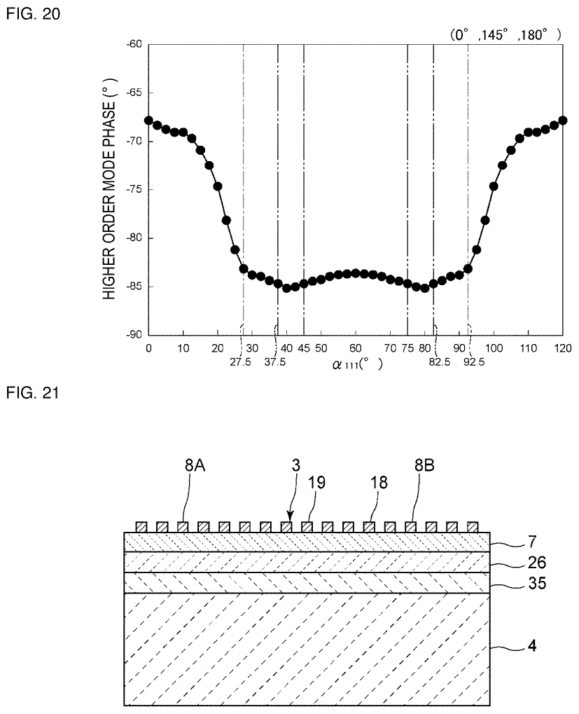

FIG. 19 is a diagram illustrating the relationship between the angle α₁₁₁ and the phase of the higher-order mode in a case where the IDT electrode is provided on the negative surface of the piezoelectric layer and the crystal orientation of the piezoelectric layer is (0°, 145°, 0°). FIG. 20 is a diagram illustrating the relationship between the angle α₁₁₁ and the phase of the higher-order mode in a case where the IDT electrode is provided on the negative surface of the piezoelectric layer and the crystal orientation of the piezoelectric layer is (0°, 145°, 180°).

As illustrated in FIGS. 19 and 20, it is clear that the higher-order mode can be more greatly reduced or prevented when the low-acoustic-velocity film is provided compared to the case illustrated in FIGS. 14 and 15. In addition, it is clear that the higher-order mode can be more effectively reduced or prevented when the angle α₁₁₁ is in the range from about 27.5° to about 92.5°, for example. Furthermore, it is clear that the higher-order mode can be even more greatly reduced or prevented when the angle am is in the range from about 37.5° to about 45° or in the range from about 75° to about 82.5° , for example. Thus, it is preferable that α₁₁₁ is in the range of about 27.5°+120°×n≤α₁₁₁≤92.5°+120°×n. It is still more preferable that α₁₁₁ lie in the range of about 37.5°+120°×n≤α₁₁₁≤45°+120°×n or in the range of about 75°+120°×n≤α₁₁₁≤82.5°+120°×n.

FIG. 21 is a front sectional view of an acoustic wave device according to a Third Preferred Embodiment of the present invention.

The present preferred embodiment differs from the Second Preferred Embodiment in that a high-acoustic-velocity film 35 is provided between the support substrate 4 and the low-acoustic-velocity film 26. In other respects, the acoustic wave device of this preferred embodiment has the same or substantially the same configuration as the acoustic wave device of the Second Preferred Embodiment.

The high-acoustic-velocity film 35 is a film having a relatively high acoustic velocity. More specifically, the acoustic velocity of bulk waves propagating through the high-acoustic-velocity film 35 is higher than the acoustic velocity of acoustic waves propagating through the piezoelectric layer 7. The high-acoustic-velocity film 35 in the present preferred embodiment is a silicon nitride film, for example. For example, the material of the high-acoustic-velocity film 35 is not limited to this material and a medium mainly including any material of aluminum oxide, silicon carbide, silicon oxynitride, silicon, sapphire, lithium tantalate, lithium niobate, quartz, alumina, zirconia, cordierite, mullite, steatite, forsterite, magnesia, diamond-like carbon (DLC), and diamond can be used.

The relationship between the angle α₁₁₁ and the phase of the higher-order mode was obtained for a case in which the IDT electrode was provided on the positive surface of the piezoelectric layer and a case in which the IDT electrode was provided on the negative surface of the piezoelectric layer under conditions differing from the those under which the relationships in FIGS. 17 to 20 were obtained only in that the high-acoustic-velocity film was provided.

High-acoustic-velocity film: Material . . . SiN, Film thickness: about 0.15λ

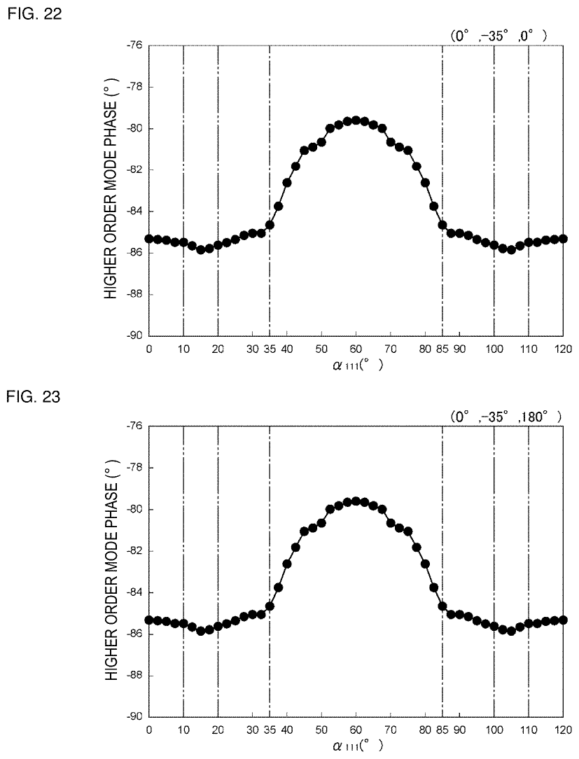

FIG. 22 is a diagram illustrating the relationship between the angle α₁₁₁ and the phase of the higher-order mode in a case where the IDT electrode is provided on the positive surface of the piezoelectric layer and the crystal orientation of the piezoelectric layer is (0°, −35°, 0°). FIG. 23 is a diagram illustrating the relationship between the angle α₁₁₁ and the phase of the higher-order mode in a case where the IDT electrode is provided on the positive surface of the piezoelectric layer and the crystal orientation of the piezoelectric layer is (0°, −35°, 180°).

As illustrated in FIGS. 22 and 23, it is clear that the higher-order mode can be more greatly reduced or prevented when the high-acoustic-velocity film is provided compared to the case illustrated in FIGS. 17 and 18. Furthermore, it is clear that the higher-order mode can be more effectively reduced or prevented when the angle α₁₁₁ is in the range from about 0° to about 35° or the range from about 85° to about 120°, for example. Note that α₁₁₁=85° is equivalent to α₁₁₁=−35° and α₁₁₁=120° is equivalent to α₁₁₁=0° due to the symmetry of the crystal structure. Furthermore, it is clear that the higher-order mode can be even more greatly reduced or prevented when the angle α₁₁₁ is in the range from about 10° to about 20° or in the range from about 100° to about 110°. Thus, it is preferable that α₁₁₁ lie in the range of about 0°+120°×n≤α₁₁₁ about 35°+120°×n or in the range of about 85°+120°×n≤α₁₁₁ about 120°+120°×n, for example. It is still more preferable that α₁₁₁ lie in the range of about 10°+120°×n≤α₁₁₁≤20°+120°×n or in the range of about 100°+120°×n≤α₁₁₁≤110°+120°×n, for example.

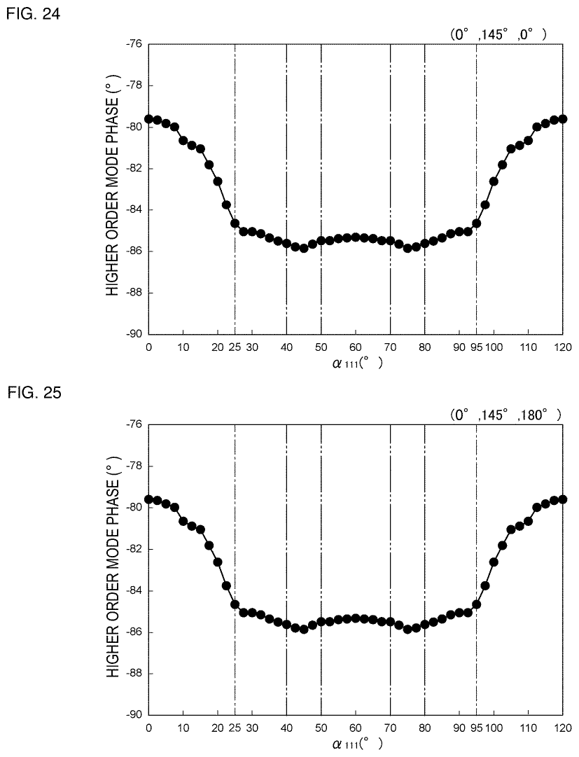

FIG. 24 is a diagram illustrating the relationship between the angle α₁₁₁ and the phase of the higher-order mode in a case where the IDT electrode is provided on the negative surface of the piezoelectric layer and the crystal orientation of the piezoelectric layer is (0°, 145°, 0°). FIG. 25 is a diagram illustrating the relationship between the angle α₁₁₁ and the phase of the higher-order mode in a case where the IDT electrode is provided on the negative surface of the piezoelectric layer and the crystal orientation of the piezoelectric layer is (0°, 145°, 180°).

As illustrated in FIGS. 24 and 25, it is clear that the higher-order mode can be more greatly reduced or prevented when the high-acoustic-velocity film is provided compared to the case illustrated in FIGS. 19 and 20. In addition, it is clear that the higher-order mode can be more effectively reduced or prevented when the angle α₁₁₁ is in the range from about 25° to about 95°, for example. Furthermore, it is clear that the higher-order mode can be even more greatly reduced or prevented when the angle α₁₁₁ is in the range from about 40° to about 50° or in the range from about 70° to about 80°, for example. Thus, it is preferable that α₁₁₁ is in the range of about 25°+120°×n≤α₁₁₁≤95°+120°×n, for example. It is still more preferable that α₁₁₁ lie in the range of about 40°+120°×n≤α₁₁₁≤50°+120°×n or in the range of about 70°+120°×n≤α₁₁₁≤80°+120°×n, for example.

In the First to Third Preferred Embodiments described above, a case is described in which the plane orientation of the support substrate is Si(111). In the present invention, the plane orientation of the support substrate is not limited to Si(111). Hereafter, a case in which the plane orientation of the support substrate is Si(110) and a case in which the plane orientation of the support substrate is Si(100) will be described as examples.

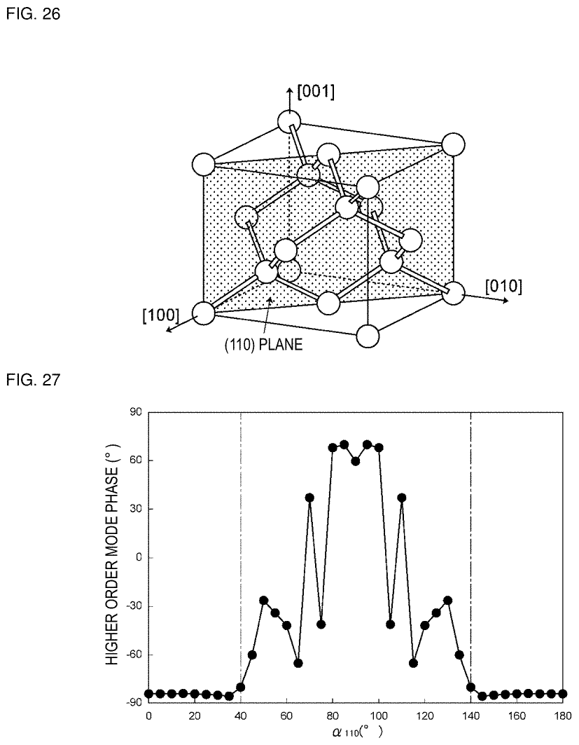

An acoustic wave device according to a Fourth Preferred Embodiment of the present invention differs from the First Preferred Embodiment illustrated in FIG. 1 in that the plane orientation of the support substrate is Si(110) and with respect to the relationship between the crystal axes of the support substrate and the piezoelectric layer. In other respects, the acoustic wave device of the present preferred embodiment has the same or substantially the same configuration as the acoustic wave device 1 of the First Preferred Embodiment. The (110) plane is the plane illustrated in FIG. 26 and the support substrate contacts the piezoelectric layer at the (110) plane.

Here, k₁₁₀ denotes a directional vector obtained when the Z_{LT} axis of the LiTaO₃ of the piezoelectric layer is projected onto the (110) plane of the support substrate. α₁₁₀ denotes the angle between the directional vector k₁₁₀ and a [001] direction of the silicon of the support substrate. In the present preferred embodiment, α₁₁₀ is in the range of about 0°+180°×n≤α₁₁₀≤40°+180°×n or in the range of about 140°+180°×n≤α₁₁₀≤180°+180°×n, where n is an arbitrary integer (0, ±1, ±2, . . . ), for example. As a result, a higher-order mode can be effectively reduced or prevented. This will be described in more detail.

The relationship between the angle α₁₁₀ and the higher-order mode was obtained. The conditions of the acoustic wave device are listed below.

Support substrate: Material . . . silicon (Si), Plane orientation . . . Si(110)

Piezoelectric layer: Material . . . rotated Y-cut X-propagation LiTaO₃, Film thickness . . . about 0.2λ, Crystal orientation of LiTaO₃ constituting piezoelectric layer: (0°, 145°, 0°)

IDT electrode: Material . . . Al, Film thickness . . . about 5% λ, Wavelength λ of IDT electrode: about 2 μm

FIG. 27 is a diagram illustrating the relationship between an angle α₁₁₀ and the phase of a higher-order mode in a case where the crystal orientation of the piezoelectric layer is (0°, 145°, 0°).

As illustrated in FIG. 27, it is clear that the higher-order mode is effectively reduced or prevented when the angle α₁₁₀ is in a range from about 0° to about 40°, for example. Similarly, it is clear that the higher-order mode is effectively reduced or prevented when the angle α₁₁₀ is in a range from about 140° to about 180°, for example. Here, when the plane orientation of the support substrate is Si(110), α₁₁₀=α₁₁₀+180° due the symmetry of the crystal structure. Therefore, α₁₁₀=140° is equivalent to α₁₁₀=−40° and α₁₁₀=180° is equivalent to α₁₁₀=0°. Therefore, a higher-order mode can be effectively reduced or prevented when α₁₁₀ is in the range of about 0°+180°×n≤α₁₁₀≤40°+180°×n or in the range of about 140°+180°×n≤α₁₁₀≤180°+180°×n, for example.

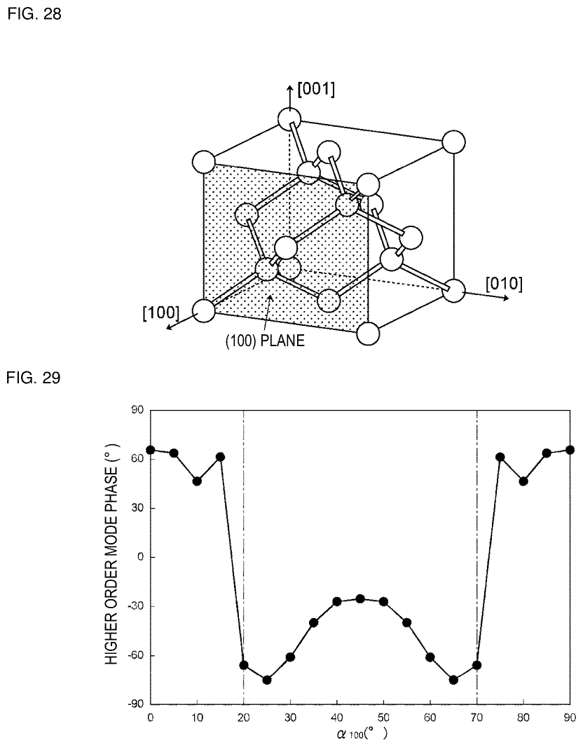

An acoustic wave device according to a Fifth Preferred Embodiment of the present invention differs from the First Preferred Embodiment illustrated in FIG. 1 in that the plane orientation of the support substrate is Si(100) and with respect to the relationship between the crystal axes of the support substrate and the piezoelectric layer. In other respects, the acoustic wave device of this preferred embodiment has the same or substantially the same configuration as the acoustic wave device 1 of the First Preferred Embodiment. The (100) plane is the plane illustrated in FIG. 28 and the support substrate contacts the piezoelectric layer at the (100) plane.

Here, k₁₀₀ denotes a directional vector obtained when the Z_{LT} axis of the LiTaO₃ of the piezoelectric layer is projected onto the (100) plane of the support substrate. α₁₀₀ denotes the angle formed between the directional vector k₁₀₀ and a [001] direction of the silicon constituting the support substrate. In the present preferred embodiment, α₁₀₀ is in the range of about 20°+90°×n≤α₁₀₀≤70°+90°×n, where n is an arbitrary integer (0, ±1, ±2, . . . ), for example. As a result, a higher-order mode can be effectively reduced or prevented. This will be described in more detail.

The relationship between the angle α₁₀₀ and the higher-order mode was obtained. The conditions of the acoustic wave device are listed below.

Support substrate: Material . . . silicon (Si), Plane orientation . . . Si(100)

Piezoelectric layer: Material . . . rotated Y-cut X-propagation LiTaO₃, Film thickness . . . about 0.2λ, Crystal orientation of LiTaO₃ constituting piezoelectric layer: (0°, 145°, 0°)

IDT electrode: Material . . . Al, Film thickness . . . 5% λ, Wavelength λ of IDT electrode: about 2 μm

FIG. 29 is a diagram illustrating the relationship between the angle α₁₀₀ and the phase of a higher-order mode in a case where the crystal orientation of the piezoelectric layer is (0°, 145°, 0°).

As illustrated in FIG. 29, it is clear that the higher-order mode is effectively reduced or prevented when the angle α₁₀₀ is in a range from about 20° to about 70°, for example. Here, when the plane orientation of the support substrate is Si(100), α₁₀₀=α₁₀₀+90° due the symmetry of the crystal structure. The higher-order mode can be effectively suppressed when α₁₀₀ is in the range of about 20°+90°×n≤α₁₀₀≤70°+90°×n, for example.

An uneven structure may be provided on the surface of the support substrate that is on the side adjacent to the piezoelectric layer in the acoustic wave devices having the configurations of the First to Fifth Preferred Embodiments described above. In this case, non-linear characteristics can be improved.

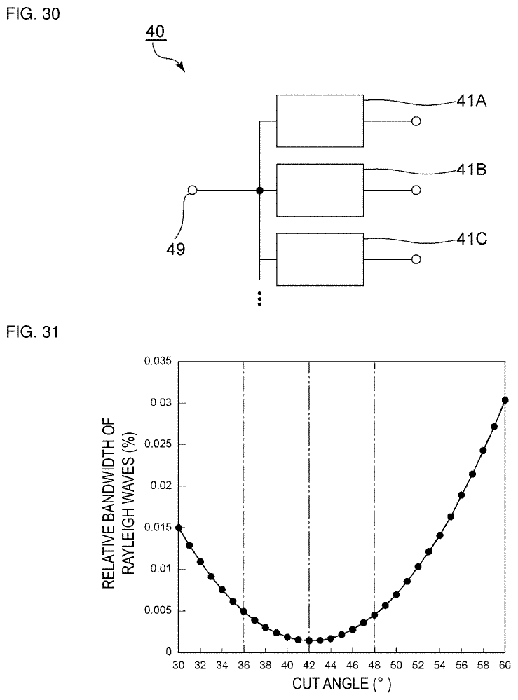

FIG. 30 is a schematic diagram of a multiplexer according to a Sixth Preferred Embodiment of the present invention.

A multiplexer 40 includes an antenna terminal 49, which is a signal terminal, that is connected to an antenna. Note that a signal terminal in the present invention is not limited to being an antenna terminal. The multiplexer 40 includes a first filter device 41A, a second filter device 41B, and a third filter device 41C that are commonly connected to the antenna terminal 49 and have different pass bands from each other. The first filter device 41A includes a first acoustic wave resonator, which is an acoustic wave device having the configuration of the First Preferred Embodiment. The second filter device 41B includes a second acoustic wave resonator, which is an acoustic wave device having the configuration of the First Preferred Embodiment. The third filter device 41C includes a third acoustic wave resonator, which is an acoustic wave device having the configuration of the First Preferred Embodiment. Note that the first to third acoustic wave resonators are not limited to the acoustic wave device of the First Preferred Embodiment, and may be any acoustic wave resonator having the configuration of an acoustic wave device according to a preferred embodiment of the present invention. It is sufficient that at least one filter device of the multiplexer 40 include an acoustic wave device according to a preferred embodiment of the present invention.

In the present preferred embodiment, the first filter device 41A, the second filter device 41B, and the third filter device 41C are band pass filters. Note that at least one of the first filter device 41A, the second filter device 41B, and the third filter device 41C may be a duplexer, for example. The number of filter devices included in the multiplexer 40 is not particularly limited. The multiplexer 40 of the present preferred embodiment also includes filter devices other than the first filter device 41A, the second filter device 41B, and the third filter device 41C. It is sufficient that a multiplexer according to a preferred embodiment of the present invention includes at least two filter devices.

Here, the pass band of the first filter device 41A is located at a lower frequency than the pass band of the second filter device 41B. The cut angle of the piezoelectric layer of the first acoustic wave resonator of the first filter device 41A is different from the cut angle of the piezoelectric layer of the second acoustic wave resonator of the second filter device 41B. More specifically, in the present preferred embodiment, the cut angle of the piezoelectric layer of the first acoustic wave resonator is from about 48° Y to about 60° Y, for example. The cut angle of the piezoelectric layer of the second acoustic wave resonator is from about 36° Y to about 48° Y, for example. In addition, for example, if the cut angle of the piezoelectric layer of the first acoustic wave resonator is about 48° Y, the cut angle of the piezoelectric layer of the second acoustic wave resonator is an angle other than about 48° Y. Here, the cut angle of the piezoelectric layer of the second acoustic wave resonator is preferably about 42°, for example. In this case, Rayleigh wave spurious responses can be reduced.

FIG. 31 is a diagram illustrating the relationship between the cut angle of the LiTaO₃ of the piezoelectric layer and the relative bandwidth of a Rayleigh wave. The relative bandwidth is expressed as {(fr−fa) /fr}×100 (%), where fr is the resonant frequency of the acoustic wave resonator and fa is the anti-resonant frequency of the acoustic wave resonator.

As illustrated in FIG. 31, it is clear that the relative bandwidth of a Rayleigh wave is narrow and the Rayleigh wave is reduced or prevented when the cut angle of the piezoelectric layer is from about 36° Y to about 48° Y, for example. In the present preferred embodiment, the cut angle of the piezoelectric layer of the second acoustic wave resonator in the second filter device 41B, which has a pass band at a higher frequency than the first filter device, is from about 36° Y to about 48° Y, for example. On the other hand, the cut angle of the piezoelectric layer of the first acoustic wave resonator in the first filter device 41A whose pass band is at lower frequency is from about 48° Y to about 60° Y, for example. Therefore, in the multiplexer 40, Rayleigh wave spurious responses can also be reduced or prevented, in addition to a higher-order mode.

It is sufficient that the cut angle of the piezoelectric layer of the first acoustic wave resonator and the cut angle of the piezoelectric layer of the second acoustic wave resonator are different from each other. For example, the cut angle of the piezoelectric layer of the first acoustic wave resonator and the cut angle of the piezoelectric layer of the second acoustic wave resonator may be different from the cut angle of the piezoelectric layer of the third acoustic wave resonator of the third filter device 41C.

An LT layer and a support substrate including silicon may be bonded to each other in order to obtain the structure in the First to Sixth Preferred Embodiments. If there is an intermediate layer, such as a low- or high-acoustic-velocity film, the intermediate layer may be provided and bonded to the LT layer or to the support substrate. As the bonding method, for example, various methods such as, for example, hydrophilic bonding, activated bonding, atomic diffusion bonding, metal diffusion bonding, anodic bonding, and bonding using resin or SOG can be used. In addition, a bonding layer formed during the bonding may be disposed at the interface of the intermediate layer or may be disposed inside the intermediate layer. In the case of the Third Preferred Embodiment, it is preferable that the bonding layer is disposed at the interface between the low-acoustic-velocity film and the high-acoustic-velocity film.

The IDT electrode is preferably provided on the negative surface of the LT layer. Defects, such as ripples, can be reduced or prevented when the IDT electrode is provided on the negative surface.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate including silicon and having a plane orientation of (111);
a piezoelectric layer directly or indirectly provided on the support substrate and in which a rotated Y-cut X-propagation lithium tantalate is included; and
an IDT electrode including a plurality of electrode fingers and directly or indirectly provided on the piezoelectric layer; wherein
a film thickness of the piezoelectric layer is less than or equal to about 1λ, where λ is a wavelength defined by an electrode finger pitch of the IDT electrode;
the piezoelectric layer includes a positive surface and a negative surface defined by a polarization direction;
when (X_{LT}, Y_{LT}, Z_{LT}) are crystal axes of the lithium tantalate of the piezoelectric layer, k₁₁₁ is a directional vector obtained by projecting the Z_{LT} axis onto the (111) plane of the support substrate, α₁₁₁ is an angle between the directional vector k₁₁₁ and an [11-2] direction of the silicon of the support substrate, and n is an arbitrary integer (0, ±1, ±2, . . . ), the angle α₁₁₁ is in a range of about 0°+120°×n≤α₁₁₁≤45°+120°×n or in a range of about 75°+120°×n≤α₁₁₁23 120°+120°×n when the IDT electrode is provided on the positive surface of the piezoelectric layer; and
the angle α₁₁₁ is in a range of about 15°+120°×n≤α₁₁₁≤105°+120°×n when the IDT electrode is provided on the negative surface of the piezoelectric layer.

2. An acoustic wave device comprising:
a support substrate including silicon and having a plane orientation of (110);
a piezoelectric layer directly or indirectly provided on the support substrate and in which rotated Y-cut X-propagation lithium tantalate is included; and
an IDT electrode including a plurality of electrode fingers and provided on the piezoelectric layer; wherein
a film thickness of the piezoelectric layer is less than or equal to about 1λ, where λ is a wavelength defined by an electrode finger pitch of the IDT electrode; and
when (X_{LT}, Y_{LT}, Z_{LT}) are crystal axes of the lithium tantalate of the piezoelectric layer, k₁₁₀ is a directional vector obtained by projecting the Z_{LT} axis onto the (110) plane of the support substrate, α₁₁₀ is an angle between the directional vector k₁₁₀ and a [001] direction of the silicon of the support substrate, and n is an arbitrary integer (0, ±1, ±2, . . . ), the angle α₁₁₀ is in a range of about 0°+180°×n≤α₁₁₀≤40°+180°×n or in a range of about 140°+180°×n≤α₁₁₀≤180°+180°×n.

3. An acoustic wave device comprising:
a support substrate including silicon and having a plane orientation of (100);
a piezoelectric layer directly or indirectly provided on the support substrate and in which rotated Y-cut X-propagation lithium tantalate is provided; and
an IDT electrode including a plurality of electrode fingers and provided on the piezoelectric layer; wherein
a film thickness of the piezoelectric layer is less than or equal to about 1λ, where λ is a wavelength defined by an electrode finger pitch of the IDT electrode; and
when (X_{LT}, Y_{LT}, Z_{LT}) are crystal axes of the lithium tantalate of the piezoelectric layer, k₁₀₀ is a directional vector obtained by projecting the Z_{LT} axis onto the (100) plane of the support substrate, α₁₀₀ is an angle between the directional vector k₁₀₀ and a [001] direction of the silicon of the support substrate, and n is an arbitrary integer (0, ±1, ±2, . . . ), the angle α₁₀₀ is in a range of about 20°+90°×n≤α₁₀₀≤70°+90°×n.

4. The acoustic wave device according to claim 1, wherein
the angle α₁₁₁ is in a range of about 10°+120°×n≤α₁₁₁≤40°+120°×n or in a range of about 80°+120°×n≤α₁₁₁≤110°+120°×n when the IDT electrode is provided on the positive surface of the piezoelectric layer; and
the angle α₁₁₁ is in a range of about 20°+120°×n≤α₁₁₁≤50°+120°×n or in a range of about 70°+120°×n≤α₁₁₁≤100°+120°×n when the IDT electrode is provided on the negative surface of the piezoelectric layer.

5. The acoustic wave device according to claim 1, wherein a low-acoustic-velocity film is provided between the support substrate and the piezoelectric layer, and an acoustic velocity of bulk waves propagating through the low-acoustic-velocity film is lower than an acoustic velocity of bulk waves propagating through the piezoelectric layer.

6. The acoustic wave device according to claim 5, wherein
a high-acoustic-velocity film is provided between the support substrate and the low-acoustic-velocity film; and
an acoustic velocity of bulk waves propagating through the high-acoustic-velocity film is higher than an acoustic velocity of acoustic waves propagating through the piezoelectric layer.

7. The acoustic wave device according to claim 1, wherein
a low-acoustic-velocity film is provided between the support substrate and the piezoelectric layer;
an acoustic velocity of bulk waves propagating through the low-acoustic-velocity film is lower than an acoustic velocity of bulk waves propagating through the piezoelectric layer;
the low-acoustic-velocity film is a silicon oxide film;
the angle α₁₁₁ is in a range of about 0°+120°×n≤α₁₁₁≤32.5°+120°×n or in a range of about 87.5°+120°×n≤α₁₁₁≤120°+120°×n when the IDT electrode is provided on the positive surface of the piezoelectric layer; and
the angle α₁₁₁ is in a range of about 27.5°+120°×n≤α₁₁₁≤92.5°+120°×n when the IDT electrode is provided on the negative surface of the piezoelectric layer.

8. The acoustic wave device according to claim 7, wherein
the angle α₁₁₁ is in a range of about 15°+120°×n≤α₁₁₁≤22.5°+120°×n or in range of about 97.5°+120°×n≤α₁₁₁≤105°+120°×n; and
when the IDT electrode is provided on the negative surface of the piezoelectric layer, the angle α₁₁₁ is in a range of about 37.5°+120°×n≤α₁₁₁≤45°+120°×n or in a range of about 75°+120°×n≤α₁₁₁≤82.5°+120°×n.

9. The acoustic wave device according to claim 7, wherein
a high-acoustic-velocity film is provided between the support substrate and the low-acoustic-velocity film;
an acoustic velocity of bulk waves propagating though the high-acoustic-velocity member is higher than an acoustic velocity of acoustic waves propagating through the piezoelectric layer; and
the high-acoustic-velocity film is a silicon nitride film.

10. The acoustic wave device according to claim 1, wherein
a low-acoustic-velocity film is provided between the support substrate and the piezoelectric layer;
an acoustic velocity of bulk waves propagating through the low-acoustic-velocity film is lower than an acoustic velocity of bulk waves propagating through the piezoelectric layer;
the low-acoustic-velocity film is a silicon oxide film;
a high-acoustic-velocity film is provided between the support substrate and the low-acoustic-velocity film;
an acoustic velocity of bulk waves propagating though the high-acoustic-velocity member is higher than an acoustic velocity of acoustic waves propagating through the piezoelectric layer;
the high-acoustic-velocity film is a silicon nitride film;
the angle α₁₁₁ is in a range of about 0°+120°×n≤α₁₁₁≤35°+120°×n or in a range of about 85°+120°×n≤α₁₁₁≤120°+120°×n when the IDT electrode is provided on the positive surface of the piezoelectric layer; and
the angle α₁₁₁ is in a range of about 25°+120°×n≤α₁₁₁≤95°+120°×n when the IDT electrode is provided on the negative surface of the piezoelectric layer.

11. The acoustic wave device according to claim 10, wherein
the angle α₁₁₁ is in a range of about 10°+120°×n≤α₁₁₁≤20°+120°×n or in a range of about 100°+120°×n≤α₁₁₁≤110°+120°×n; and
the angle α₁₁₁ is in a range of about 40°+120°×n≤α₁₁₁≤50°+120°×n or in a range of about 70°+120°×n≤α₁₁₁≤80°+120°×n when the IDT electrode is provided on the negative surface of the piezoelectric layer.

12. A multiplexer comprising:
a signal terminal; and
a plurality of filter devices commonly connected to the signal terminal, each including the acoustic wave device according to claim 1, and each having different pass bands from each other; wherein
a cut angle of the piezoelectric layer of the acoustic wave device of one filter device among the plurality of filter devices and a cut angle of the piezoelectric layer of the acoustic wave device of at least one other filter device among the plurality of filter devices are different from each other.

13. The multiplexer according to claim 12, wherein among the plurality of filter devices, the cut angle of the piezoelectric layer of a filter device whose pass band is located at a lower frequency is from about 48° Y to about 60° Y and the cut angle of the piezoelectric layer of a filter device whose pass band is located a higher frequency than the pass band of the aforementioned filter device is from about 36° Y to about 48° Y.

14. The acoustic wave device according to claim 2, wherein a low-acoustic-velocity film is provided between the support substrate and the piezoelectric layer, and an acoustic velocity of bulk waves propagating through the low-acoustic-velocity film is lower than an acoustic velocity of bulk waves propagating through the piezoelectric layer.

15. The acoustic wave device according to claim 14, wherein
a high-acoustic-velocity film is provided between the support substrate and the low-acoustic-velocity film; and
an acoustic velocity of bulk waves propagating through the high-acoustic-velocity film is higher than an acoustic velocity of acoustic waves propagating through the piezoelectric layer.

16. The acoustic wave device according to claim 3, wherein a low-acoustic-velocity film is provided between the support substrate and the piezoelectric layer, and an acoustic velocity of bulk waves propagating through the low-acoustic-velocity film is lower than an acoustic velocity of bulk waves propagating through the piezoelectric layer.

17. The acoustic wave device according to claim 16, wherein
a high-acoustic-velocity film is provided between the support substrate and the low-acoustic-velocity film; and
an acoustic velocity of bulk waves propagating through the high-acoustic-velocity film is higher than an acoustic velocity of acoustic waves propagating through the piezoelectric layer.
